(19) United States
(12) Patent Application Publication
(10) Pub. No.: US 2003/0168333 A1
(43) Pub. Date: Sep. 11, 2003

(54) Metal or metal alloy based sputter target and method for the production thereof

(76) Inventors: Martin Schlott, Offenbach (DE); Josef Heindel, Hainburg (DE)

Correspondence Address: SHERIDAN ROSS PC, 1560 BROADWAY, SUITE 1200, DENVER, CO, 80202

(21) Appl. No.: 10/257,118

(22) PCT Filed: Mar. 23, 2001
(86) PCT No.: PCT/EP01/03310

(30) Foreign Application Priority Data
Apr. 7, 2000 (DE) 100 17 414.0

(51) Int. Cl. C23C 14/32; B22F 1/00; B22F 1/02; C25B 11/00; C22C 18/00; C22C 28/00; C22C 12/00; C22C 13/00; C22C 21/00; C25B 13/00; C25B 9/00; C23C 14/00

(52) U.S. Cl. 204/192.13; 204/298.12; 419/30; 420/513; 420/528; 420/555; 420/557; 420/577

(57) ABSTRACT

The invention concerns a sputter target on a metal or metal alloy base with a melting point of not more than 750° C., especially tellurium alloy, with a microstructure of powder particles compacted by means of powder metallurgy, where the primary microstructure of the powder particles is very fine as compared with their size and where the particle size is clearly greater than the grain size of the primary microstructure.

The present invention concerns a sputter target on a metal or metal alloy base and preferably with a melting point of less than 750° C.

The invention also concerns a process for the production of a sputter target on a metal or metal alloy base, preferably with a melting point of less than 750° C.

Quite a few sputter targets have to be made of metal or alloys that either do not lend themselves to being produced by means of a casting process or do so only with considerable difficulty.

For phase-change disks, for example CD-RW, DVD-RW or DVD-RAM, it is a common practice to use, among others, complex multiphase alloys, often with a predominant tellurium content. For the purposes of the phase-change principle, moreover, it is customary to produce sputter targets for the deposition of layers for appropriate optical storage media, optical storage disks for example, where the layer structure due to light pulses is either amorphous or crystalline. These targets can be produced, for example, by means of a casting process that yields a shape close to the final one as disclosed and discussed, for example, in DE-OS 197 10 903.

However, relatively coarse grains or microstructure components are formed during the casting. Targets produced in this manner have pores and tend to form cracks when they are mechanically stressed. Furthermore, it has been found that when this production mode is used with alloys that have a broad solidification interval, it leads to segregation and therefore also to macroscopically inhomogeneous targets.

Another customary production process uses alloyed powders as starting material. The first step is to cast plates having the required alloy composition. These plates are then ground into powders in the size range<300 μm. Substantially finer powders can be produced only at a substantial cost, because the work will have to be carried out under an inert gas if the oxygen content is to be kept low. Attempts have already been made to obtain fine-grained powders by means of conventional gas atomization processes, but these are once again rather costly. In the case of metals with a high vapour pressure, for example when sputter targets are produced on zinc or tellurium alloy bases, the atomization is associated with considerable evaporation losses and a corresponding contamination of the plant that has to be regarded as critical. Furthermore, the evaporation also leads to a modification of the powder stoichiometry.

The targets produced by means of conventional casting and grinding have the disadvantage that their microstructure is usually rather coarse. The size of the individual grains and/or the precipitated intermetallic phases reaches up to the maximum size of the employed powder particles, that is to say, up to several hundred μm. This can lead to an inhomogeneous layer composition. Furthermore, a very rough surface will form on such targets during the sputter erosion. Another drawback is due to the fact that the individual coarse components of the structure will at times be incompletely incorporated, because they are surrounded by thin and brittle oxide skins. This can lead to such anomalous discharges as arcing and high particle rates with corresponding negative effects on the accuracy of the storage layer.

If one diminishes the size of the powder particles, the oxygen content will rise very quickly from a few hundred ppm to several thousand ppm when the material is ground in air. This may not only lead to poor layer properties, but such targets will also be tendentially more prone to tear, because the fact that the particle surfaces are covered with oxides will prevent their becoming welded together upon compaction. The only remedy would consist of grinding and handling under an inert gas of high purity and this could hardly be tolerated from the point of view of cost.

Aluminium targets with small additions of other elements, for example beryllium, chromium, titanium, tantalum, rare earths, etc., are used for various applications, reflection layers or strip conductors being cases in point. Customary production processes are either casting and rolling of blocks, spray forming or pressure-supported compaction of atomized powders.

Segregations and structure inhomogeneities are often observed during the solidification of cast blocks. Moreover, the precipitates tend to be rather coarse, and all this has negative effects on the sputter characteristics. Even a subsequent mechanical working does not substantially improve the situation.

The spray compaction alternative is a very expensive process that is suitable and becomes economic only when production quantities are very large. Moreover, one has to allow for considerable material losses, the so-called “overspray”. Depending on the demands that are to be made on the material, an after-compaction will generally become necessary to eliminate porosity.

Given the reactivity of aluminium, the pressure-supported compaction of atomized powders calls for the protection of an expensive inert gas technique. This is associated with the great danger of the formation of cross contaminations deriving from previous atomizations.

Lastly, various alloys with a low melting point, for example bismuth with slight additions of other materials or tin-zinc alloys are used for the coating of architectural glass.

Bismuth targets are usually produced by means of powder metallurgy, where the powders have hitherto been produced by means of the mechanical grinding of alloy blocks, this being due to cost considerations. But this once again leads to a powder with coarse segregations of the alloying material. Targets experimentally produced with very expensive atomized powders are characterized by a clearly finer structure. As already said, they are however particularly expensive.

Tin-zinc targets are produced either by means of casting and rolling of large blocks or by means of the direct filling of copper boats with partially liquid alloy. In both cases the long solidification interval of the alloy leads to an inhomogeneous structure with considerable macroscopic segregations. This has negative effects on the sputter behaviour and the homogeneity of the layer properties.

The invention therefore sets out to provide a sputter target that will be characterized by both a fine-grained structure and a low oxygen content and a process for the production of such targets that will not have to have recourse to costly grinding or atomization under the protection of highly pure inert gases. In this way the invention seeks to make available sputter targets that will make it possible to use cathode atomization to produce layers with very good layer properties, possibly layers that store in accordance with the phase-change principle.

As far as the product is concerned, the invention attains this aim by means of a sputter target characterized by particles with a fine or primary structure that, as compared with particle size, represents a markedly fine microstructure.

A particularly advantageous feature of the sputter target in accordance with the invention is therefore the fact that—at least at first and with ultimately beneficial effects on cost—it employs a relatively coarse particle structure, although the particles in accordance with the invention are already characterized by a fine primary structure. The particles, in fact, have a size that is clearly greater than the grains and/or the precipitation phases of the very fine primary structure. Subsequently—and without incurring great costs—the particles can be further processed in an ultimately known manner to obtain a finer powder without this being accompanied by a substantial increase of the oxygen content and also without having to carry out the work in an inert gas box. When this is done, advantage can be taken of the fact that the fine or primary structure of the particle already defines something like fracture lines within the particles that facilitate the refinement of the initially coarse particle structure and render it easy even when only simply means are used.

Favourable particle size distributions in this connection lie in the region of 50 and 1000 μm, especially 50 and 600 μm, where the grain sizes or sizes of individual precipitated phases of the microstructure may be such that at least 70%, especially 80%, are smaller than 30 μm. Depending on the particular metal or alloy, the size, especially in the case of precipitations, may even lie below 10 μm. Typically, the oxygen content of the alloys may be in the region of 200 to 300 ppm, where even in the case of a subsequent pulverization exploiting the primary structure will increase the oxygen content only to, for example 600 ppm. In any case, the oxygen content can be maintained clearly below 1000 ppm. A subsequent compaction employing means that as such are known, pressing or sintering for example, supported by appropriate temperatures and pressures, may make it possible to attain densities that amount to at least 95% of the theoretical density.

The sputter target in accordance with the invention may contain alloying components in non-equilibrium condition or in the form of a supercooled melt, this at least prior to a possible further heat treatment.

The particles will be especially in the form of granules.

The alloy used for the sputter target in accordance with the invention will preferably be on an aluminium, bismuth, indium, tin, antimony, tellurium or zinc base. In all cases, however, the alloys will have a melting point of less than 750° C.

The fine or primary structure of the particles that exists in the sputter target in accordance with the invention is attained in the process in accordance with the invention—an independent solution of the task defined hereinabove for which independent protection is also requested—in such a way that a melting process, for example the melting down of one or more pre-existing alloys, is followed by bringing the melt into direct contact with a cooling substance that accelerates the solidification process and leads to the formation of granules or coarse powder grains. When the melt is poured out to come into contact with the cooling substance, the pouring stream is chosen in such a manner as to form granules of the desired size, possibly a pouring stream having a diameter of the order of 2 to 6 mm. Especially the softer metals, cases in point being aluminium, tin and zinc, can be pressed right away. Otherwise it would be desirable to grind the material down to a smaller size. The granules are produced in a size up to 6 mm and when they are of this size, possibly in the case of an aluminium alloy, can be directly processed into sputter targets. Preferably, however, the granules will have their size reduced in a mill and, more precisely, to particles in the range between 0.05 and 1.00 mm, especially for alloys on a tellurium and bismuth base. This is followed by compaction into a sputter target under pressure and/or temperature.

Other than in prior art as described, for example, in the previously mentioned DE-OS 197 10 903, the process in accordance with the invention thus does not wait for the so-called natural solidification of a melt, in which a crucible or other melting pot is cooled on its underside or its external circumference, so that a solidification front will advance either in the direction normal to the surface of the melt or in the direction parallel thereto, but the melt is rather brought into direct contact with a cooling substance in order to form granules having a size in the region up to 6 mm, which—depending on the particular alloy—may then be further reduced to a particle size smaller than 1 mm, which can be done in a mill. The solidification process—and at the same time also the structuring process in accordance with the invention—will be favourably affected if the melt itself is spread or fanned out by being poured out of the crucible. It is particularly advantageous if the melt is poured into a cooling medium, preferably water, in order to obtain the desired fine-structure granules. Quenching in water obtains particularly favourable results in relation to the desired particle size and their formation with a very fine primary microstructure. In this connection the pouring stream into the cooling medium is set in such a manner as to obtain the desired granule having a size of up to 6 mm. With a tellurium alloy and a bismuth and aluminium alloy, good results have been obtained with a pouring stream in the range between 2 and 6 mm. On the basis of these granules it is possible to produce, for example, sputter targets for the production of layers (coatings) for disks with the desired good writing, reading and storage properties. These targets are distinguished by a very smooth surface, which facilitates the liberation of sputter particles and thus makes it possible to obtain sputter rate increases of up to 10%.

Alternatively, one may consider pouring the melt onto a cooling body, especially a cooling plate, where the cooling body may also be made to rotate in order to facilitate the spreading or fanning out of the melt due to the action of centrifugal forces.

All said and done, the fine or primary structuring of the particles is obtained by virtue of the fact that the melt is “quenched” and subjected to a kind of “shock solidification”.

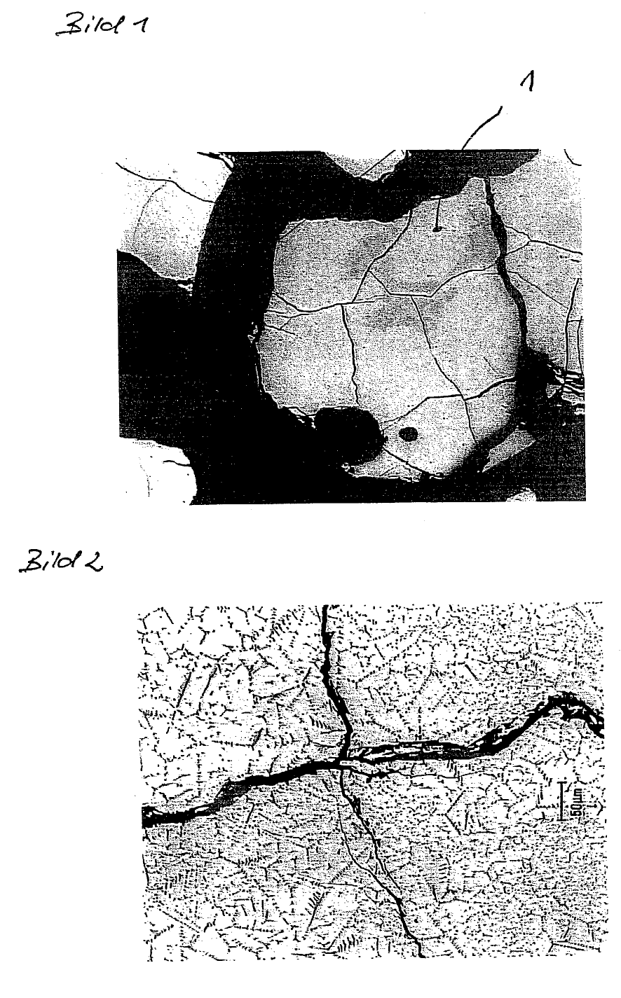

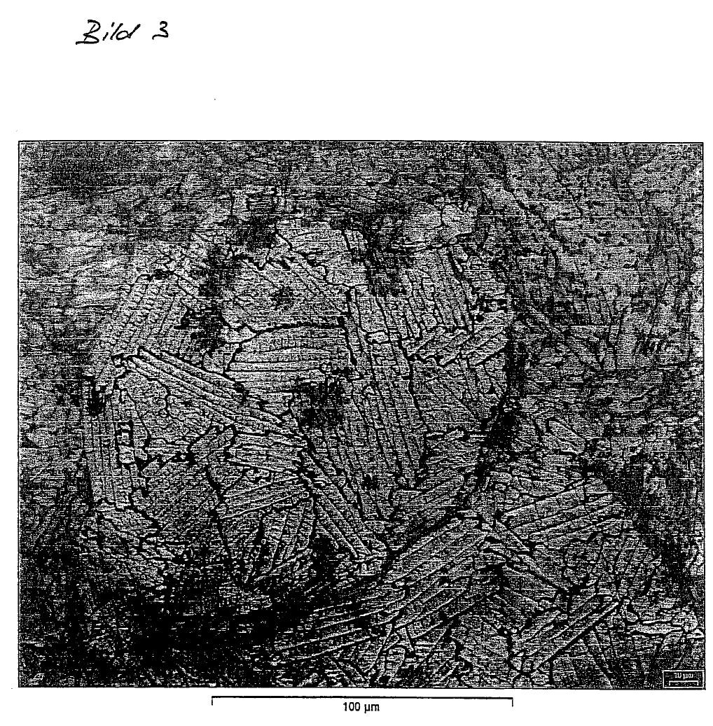

FIG. 1 shows several granules, where the reference number 1 indicates a granule that can here be seen to have a round formation and to be traversed by several cracks. During the further processing this granule may break up into particles. The granule itself and/or its component particles have the fine structure as their primary structure that can be seen in FIG. 2, this figure providing a rather clear illustration of the coarse structure of the particles and the fine structure within these particles. FIG. 2 very clearly brings out the somewhat broader boundary lines between three to four larger particles that, in their turn, are structured much more finely at the level of their primary structure. Indicated in the figure is a scale of 50 μm. It can clearly be seen that the primary structure is characterized by a clearly smaller magnitude of its component parts. FIG. 1 shows a granule of Ge₂Sb₂Te₅ alloy that was quenched in water at a magnification of 50:1, while FIG. 2 shows the particles of an AgInSbTe alloy at a magnification of 200:1.

FIG. 3 shows the microstructure of a target with an alloy in accordance with FIG. 2, but at an even greater magnification to give a better idea of the fine structure. It is essentially made up of grains similar to a brick with a typical length in the range between 30 μm and 100 μm—note that the figure also brings out the contours of two grains produced by means of grinding—from which the sputter target is then formed by appropriate compaction of the particles under pressure and/or temperature. FIG. 3 very clearly shows the fine structure within a grain.

By way of embodiment (implementation) examples, a number of targets were produced from bismuth alloys, the bismuth of the alloys in question always being accompanied by a transition metal of the manganese, iron, cobalt series, with the percentage of the transition metal in the range up to 2% by weight. The material was molten down in an inert gas atmosphere inside a furnace heated by means of an electric resistance, followed by the pouring of the melt into a water basin at 360° C. through a nozzle having a diameter of 4 mm. A scattered granule several millimetres in size was obtained. The coarsely ground granule contains very fine precipitations of the residual eutectic. The primary microstructure resembles the one shown in FIG. 2.

1. A sputter target on a metal or metal alloy base with a melting point of not more than 750° C., especially tellurium alloy, characterized by a microstructure of particles with a primary microstructure that is very fine as compared with particle size.

2. A sputter target characterized in that the primary microstructure comprises grains and/or precipitation phases of which at least 70%, but preferably 80%, have a size smaller than 30 μm.

3. A sputter target in accordance with claim 1 or claim 2, characterized in that the particles have a size in the range between 0.05 and 6.00 mm, preferably smaller than 1.0 mm, and particularly preferably smaller than 0.6 μm.

4. A sputter target in accordance with any one of the preceding claims, characterized in that the particles have an oxygen content of less than 1000 ppm, especially less than 600 ppm and especially in the range between 200 and 300 ppm.

5. A sputter target in accordance with any one of the preceding claims, characterized in that the particles are formed from granules or ground granules.

6. A sputter target in accordance with any one of the preceding claims, characterized in that the granules are formed by means of quenching of the melt in or on a cold medium.

7. A sputter target in accordance with claim 6, characterized in that the granules are formed by pouring the melt into water.

8. A sputter target in accordance with claim 6, characterized in that the granules are formed by pouring the melt onto a cooled and preferably rotating metal plate.

9. A sputter target in accordance with any one of the preceding claims, characterized by the alloying components being in a non-equilibrium state or in the form of a supercooled melt.

10. A sputter target in accordance with any one of the preceding claims, characterized in that the particles are consolidated under the effect of temperature and/or pressure.

11. A sputter target in accordance claim 10, characterized in that its density amounts to at least 95% of the theoretical density.

12. A sputter target in accordance with any one of the preceding claims, characterized in that it contains an alloy on an aluminium (Al), bismuth (Bi), indium (In), tin (Sn), antimony (Sb), tellurium (Te) or zinc (Zn) base.

13. A sputter target in accordance with claim 11, characterized in that it contains admixtures, especially admixtures of conventional powders.

14. A sputter target in accordance with claim 12, characterized in that the admixtures account for up to 20% by weight.

15. A process for the production of a sputter target on a metal or a metal alloy base, preferably with a melting point of not more than 750° C., characterized by a melting process and a subsequent solidification process accelerated by bringing the melt into direct contact with a liquid cooling medium or a solid cooling body in order to obtain the formation of granules that are then compacted into a sputter target under the action of pressure and/or temperature, possibly after having undergone a further size reduction to particles.

16. A process in accordance with claim 15, characterized in that the melt is brought into contact with a preferably liquid cooling medium, especially water, especially poured into water, where the melt jet for the pouring into water is set to a thickness of 2-6 mm for the desired granule formation.

17. A process in accordance with claim 15, characterized in that the melt is poured onto a cooling body especially in the form of a plate.

18. A process in accordance with claim 17, characterized in that the cooling body rotates.

19. A process in accordance with any one of claims 15 to 18, characterized in that the granules are pulverized after solidification.

20. A process in accordance with any one of claims 15 to 19, characterized in that the granules are reduced to particles of the order of magnitude of 0.05 to 1.0 mm, especially smaller than 0.6 mm.

21. A process in accordance with any one of claims 15 to 20, characterized in that the alloy used has an aluminium (Al), bismuth (Bi), indium (In), tin (Sn), antimony (Sb), tellurium (Te) or zinc (Zn) base.
